(19) United States
(12) Patent Application Publication
(10) Pub. No.: US 2004/0137740 A1
(43) Pub. Date: Jul. 15, 2004

(54) Method to reduce dishing, erosion and low-k dielectric peeling for copper in low-k dielectric CMP process

(75) Inventors: Chi-Wei Chung, You Liu City (TW); Ying-Ho Chen, Taipei (TW); Syun-Ming Jang, Hsin-Chu (TW); Tsu Shih, Hsin-Chu (TW)

Correspondence Address: GEORGE O. SAILE & ASSOCIATES, 28 DAVIS AVENUE, POUGHKEEPSIE, NY, 12603, US

(73) Assignee: Taiwan Semiconductor Manufacturing Company

(21) Appl. No.: 10/345,762

(22) Filed: Jan. 15, 2003

(51) Int. Cl. H01L 21/302; H01L 21/461

(52) U.S. Cl. 438/692

(57) ABSTRACT

A new method of Chemical Mechanical Polishing of copper surfaces. During the process of CMP and at predetermined instances within the process of CMP, Surface Active Agents of different concentrations are added as a polishing agent of the copper surface that is being polished.

### BACKGROUND OF THE INVENTION

(1) Field of the Invention

The invention relates to the fabrication of integrated circuit devices, and more particularly, to a method of avoiding negative effects of surface dishing, surface erosion and dielectric peeling when applying Chemical Mechanical Polishing to copper surfaces created in low-k dielectrics.

(2) Description of the Prior Art

A significant aspect of the creation of semiconductor devices relates to the interconnection of these devices. For these interconnections, metals such as aluminum or their alloys have been used extensively in the past, in more recent developments copper is becoming the preferred material. Copper has of late been the material of choice in view of the more attractive performance characteristics of copper such as a low cost and low resistivity. Copper however has a relatively large diffusion coefficient into surrounding dielectrics such as silicon dioxide and silicon. Copper that forms a conductive interconnect may diffuse into the surrounding dielectric such as a silicon dioxide layer, causing the dielectric to be conductive and decreasing the dielectric strength of the silicon dioxide layer. Copper interconnects are therefore preferably encapsulated by at least one diffusion barrier to prevent diffusion into the silicon dioxide layer. Silicon nitride is a diffusion barrier to copper, but the prior art teaches that the interconnects should not lie on a silicon nitride layer because it has a high dielectric constant compared with silicon dioxide. The high dielectric constant causes an undesired increase in capacitance between the interconnect and the substrate. Copper further has low adhesive strength to various insulating layers, while it has been proven inherently difficult to mask and etch a blanket copper layer into intricate circuit structures.

While copper has become important for the creation of multilevel interconnections, copper lines frequently show damage after CMP and clean. This in turn causes problems with planarization of subsequent layers that are deposited over the copper lines since these layers may now be deposited on a surface of poor planarity. Isolated copper lines or copper lines that are adjacent to open fields are susceptible to damage. Where over-polish is required, the problem of damaged copper lines becomes even more severe.

The increasing need to form planar surfaces in semiconductor device fabrication has led to the development of a process technology known as Chemical Mechanical Planarization (CMP). In the CMP process, semiconductor substrates are rotated, face down, against a polishing pad in the presence of abrasive slurry. Most commonly, the layer to be planarized is an electrical insulating layer overlaying active circuit devices. As the substrate is rotated against the polishing pad, the abrasive force grinds away the surface of the insulating layer. Additionally, chemical compounds within the slurry undergo a chemical reaction with the components of the insulating layer to enhance the rate of removal. By carefully selecting the chemical components of the slurry, the polishing process can be made more selective to one type of material than to another. For example, in the presence of potassium hydroxide, silicon dioxide is removed at a faster rate than silicon nitride. The ability to control the selectivity of a CMP process has led to its increased use in the fabrication of complex integrated circuits.

Conventional methods of Chemical Mechanical Polishing (CMP) are known to cause problems of peeling of the surrounding low-k dielectric and of dishing and corrosion of the polished copper surface. Over polishing is frequently required in order to assure a copper surface of good planarity and acceptable granularity. The invention addresses problems of surface dishing, erosion and low-k dielectric peeling by adding

U.S. Pat. No. 6,376,361 B1 (Chooi et al.) shows a copper and low-k chemical mechanical polish (CMP) process using surfactants.

U.S. Pat. No. 6,376,381 (Sabde) reveals a CMP process for copper and dielectrics using surfactants.

U.S. Pat. No. 6,1372,632 B1 (Yu et al.) shows a copper CMP and surfactants.

### SUMMARY OF THE INVENTION

A principle objective of the invention is to provide a method of polishing copper surfaces whereby negative effects of surface dishing, surface corrosion and peeling of surrounding low-k dielectric are avoided.

In accordance with the objectives of the invention a new method of Chemical Mechanical Polishing of copper surfaces. During the process of CMP and at predetermined instances within the process of CMP, Surface Active Agents of different concentrations are added as a polishing agent of the copper surface that is being polished.

### BRIEF DESCRIPTION OF THE DRAWINGS

FIG. 1 shows a prior art method of CMP.

FIG. 2 shows a flowchart of the intervals and therewith-related steps that are provided during the process of polishing a copper surface.

### DESCRIPTION OF THE PREFERRED EMBODIMENTS

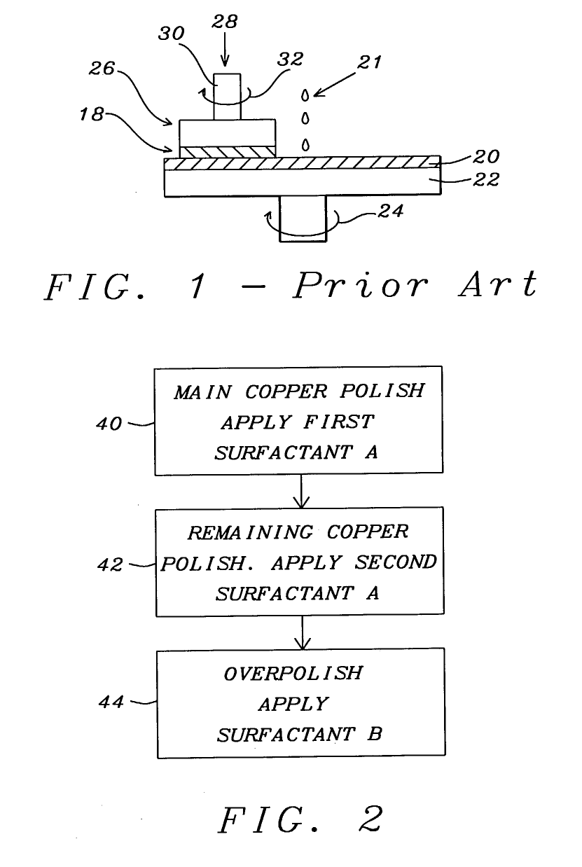

FIG. 1 shows a Prior Art CMP apparatus. A polishing pad 20 is affixed to a circular polishing table 22 that rotates in a direction indicated by arrow 24 at a rate in the order of 1 to 100 RPM. A wafer carrier 26 is used to hold wafer 18 face down against the polishing pad 20. The wafer 18 is held in place by applying a vacuum to the backside of the wafer (not shown). The wafer 18 can also be attached to the wafer carrier 26 by the application of a substrate attachment film (not shown) to the lower surface of the wafer carrier 26. The wafer carrier 26 also rotates as indicated by arrow 32, usually in the same direction as the polishing table 22, at a rate on the order of 1 to 100 RPM. Due to the rotation of the polishing table 22, the wafer 18 traverses a circular polishing path over the polishing pad 20. A force 28 is also applied in the downward vertical direction against wafer 18 and presses the wafer 18 against the polishing pad 20 as it is being polished. The force 28 is typically in the order of 0 to 15 pounds per square inch and is applied by means of a shaft 30 that is attached to the back of wafer carrier 26.

A typical CMP process involves the use of a polishing pad made from a synthetic fabric and a polishing slurry, which includes pH-balanced chemicals, such as sodium hydroxide, and silicon dioxide particles.

Abrasive interaction between the wafer and the polishing pad is created by the motion of the wafer against the polishing pad. The pH of the polishing slurry controls the chemical reactions, e.g. the oxidation of the chemicals that comprise an insulating layer of the wafer. The size of the silicon dioxide particles controls the physical abrasion of surface of the wafer.

The polishing pad is typically fabricated from a polyurethane (such as non-fibrous polyurethane, cellular polyurethane or molded polyurethane) and/or a polyester-based material. Pads can for instance be specified as being made of a microporous blown polyurethane material having a planar surface and a Shore D hardness of greater than 35 (a hard pad).

Polishing slurry 21 conventionally comprises pH-balanced chemicals, such as sodium hydroxide, and silicon dioxide particles. The polishing slurry is instrumental in the polishing of the wafers. Abrasive forces are created by the motion of the wafer against the polishing pad while the pH of the polishing slurry controls the chemical reactions, such as the oxidation of the chemicals which comprise an insulating layer of the wafer, the size of the silicon dioxide particles controls the physical abrasion of surface of the wafer. The polishing of the wafer is accomplished when the silicon dioxide particles, contained in the slurry, wear down the oxidized chemicals.

The amount of material removed during CMP polishing is dependent on the density of the pattern contained in the layers that are polished whereby the amount of material that is removed depends on the density of raised areas on the layer that is polished. In polishing semiconductor wafers, the polishing time and the downforce exerted on a wafer by a polishing fixture are typically fixed, regardless of the topography of the particular layer that is polished. The relationship between the polishing removal rate of material, the downforce exerted on the wafer and the surface area that is polished is expressed by Preston's law, which states that the removal rate of material from a wafer is proportional to the downforce exerted on the wafer and inversely proportional to the surface area of the wafer that comes into contact with the polishing pad. Generally, for a fixed downforce, Preston's law shows that the removal rate of material increases as the polished surface decreases, and visa versa. As such, the rate of material removal during CMP may be inconsistent from integrated circuit to integrated circuit, as well as to from layer to layer over the surface of a single wafer that contains at least one integrated circuit, since a wide variation exists in the feature concentration of raised areas.

As part of the polishing operation during the process of CMP, the applied slurry and the therein-contained removed particles are aggressively removed from the surface that is being polished. The removed substance, in the instance where copper surfaces embedded in low-k dielectrics are polished, contains a high concentration of copper particles. The removed substance, optionally combined with added substances, is referred to as the Surface Active Agent or surfactant, since this substance affects the polishing of the surface.

By creating different concentrations of materials in the surfactant, different surfactants can be created such as surfactant A and surfactant B. It is clear that, during the early phase of copper polishing, the concentration of copper particles in the removed slurry is relatively high since the initial polishing action typically polishes an uninterrupted copper surface.

By now dividing the complete CMP process into three stages, the following can be observed:

1. During the Main Phase of copper polishing, 70% to 80% of the copper is removed, resulting in a high concentration (0.2 wt %) of copper particles in the surfactant; this surfactant can be designated as being surfactant A

2. During the Balance Phase of the copper polishing, 20% to 30% of the copper is removed, resulting in a lower concentration (0.1 wt %) of copper particles in the surfactant; surfactant A can be applied to obtain an optimal copper removal rate

3. During the Over-Polishing Phase, a surfactant B can be applied, which comprises a chemical component that is aimed at reducing the copper etching rate and which has as specific purpose to reduce effects of dishing and erosion and to further increase hydrophobic wetting of the surface of the low-k dielectric, thereby preventing low-k dielectric surface wetting.

To summarize using the flowchart of FIG. 2 for this purpose:

During the Main Phase of copper removal, FIG. 2, step 40, between about 70 and 80% of the copper is removed of the surface that is being polished; surfactant A1 is applied to the surface that is being polished, surfactant having a high copper concentration of about 0.2 wt %; by therefore collecting and re-applying surfactant A during the initial copper surface polishing, the copper removal rate can be enhanced, resulting in increased removal of the polished layer of copper

During the Balance Phase of copper removal, FIG. 2, step 42, surfactant A2 is applied to the surface that is being polished, surfactant having a lower copper concentration of abut 0.1 wt %; by collecting and re-applying the removed concentration, this surfactant can be optimally applied for control of erosion and dishing of the polished copper surface

During the Over-polishing Phase, FIG. 2, step 44, surfactant B is applied to the surface that is being polished, surfactant B having been provided with a chemical agent that reduces copper etching rate in addition to being provided with a wetting agent for low-k dielectric surfaces.

To summarize the invention:

The invention collects and re-applies concentrations of material removed from a copper surface that is being polished

The invention distinguishes between the various stages of polishing a copper surface, that is the first and second initial stage and a final stage of copper surface polishing

During the first initial stage of polishing a copper surface, most of the copper is removed from the surface; by re-applying the removed concentrations as surfactant, the polishing rate of the copper surface is increased

During the second initial stage, relatively little copper is removed from the copper surface that is being polished, modifying the composition of the concentration that is removed from the polished surface and making this concentration better suited for purposes of control of erosion and dishing in addition to optimizing the copper removal rate

During the final stage of polishing a copper surface, that is during over-polish, a surfactant can be created and applied that is particularly aimed at reducing the copper removal rate, at reducing copper surface erosion and surface dishing and at increasing low-k dielectric hydrophobic surface wetting to prevent delamination.

The conventional method and the method of the invention will next be summarized.

The conventional method of polishing a copper surface, applying a commercial copper slurry, comprises:

A fixed surfactant type and content during the complete process of polishing a copper surface, and

It a difficult to simultaneously observe a high copper removal rate, the creation of good planarity and the presence or absence of low-k dielectric peeling.

The invention provides for:

1. Adding a different type and different content surfactant during the copper polishing stage

2. A multi-step copper polishing process, comprising:

Bulk copper removal by adding a higher concentration (0.2 wt %) surfactant A to increase the copper removal rate

Remaining copper removal and EPD etching and over-polish; for the latter a lower concentration (0.1 wt %) surfactant B can be sued to get the optimum copper removal rate and to enhance planarity creation; at the saem time, the peeling of surrounding low-k dielectric can be prevented by increasing the low-k hydrophobic surface.

Specifically highlighted below are details regarding surfactants A and B.

Surfactant A

Chemical structure:

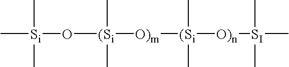

Surfactant yields smaller abrasive particle size (150-200 nm), the particle size can be evaluated using for instance an automatic 4700 laser beam scattering system, and

The principle for applying surfactant A is based on:

1. For copper CMP, the copper Removal Rate (RR) is proportional to the total contact area between the abrasive particles and the copper surface at a fixed solid concentration of copper

2. As a consequence, smaller abrasive particles correspond to a larger contact are and therefore to a higher copper RR.

Surfactant B

Chemical structure:

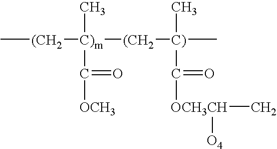

Improve the wettability of slurries on the low-k surface and increase slurry viscosity

Contact angle: non-surfactant B: 68 degrees, and

With surfactant B: 45 degrees.

It must thereby be noted that surfactant A and B are nonionic and solution-derived polymers with a weight average molecular weight in the range between about 2,000 and 3,000.

Following are typical processing conditions that are applied by the invention:

Tool: Lam Teres 200 mm linear polished

Slurry pH between about 9 and 10

Surfactant content: between about 5*10-4 g/L and 10-4 g/L

DF/BS: bulk removal: 3 psi/400 fpm (downforce/belt speed) remaining copper removal and EPD etching: 2 psi/400 fpm

Copper Removal Rate: bulk removal between about 6,000 and 7,000 Angstrom/min.

remaining copper removal and EPD etching, between about 2,000 and 3,000 Angstrom/min.

Although the invention has been described and illustrated with reference to specific illustrative embodiments thereof, it is not intended that the invention be limited to those illustrative embodiments. Those skilled in the art will recognize that variations and modifications can be made without departing from the spirit of the invention. It is therefore intended to include within the invention all such variations and modifications which fall within the scope of the appended claims and equivalents thereof.

What is claimed is:

1. A method of reducing copper surface dishing and erosion and low-k dielectric delamination, comprising:
providing a substrate, a patterned layer of copper having been created in a layer of low-k dielectric deposited over the surface of the substrate; and
polishing during three polishing intervals the patterned layer of copper, the three polishing intervals comprising:
a first polishing interval, supplying a higher concentration Surface Active Agent A (Surfactant A);
a second polishing interval, supplying a lower concentration Surface Active Agent A (Surfactant A); and
a third polishing interval, supplying Surface Active Agent B (Surfactant B).

2. The method of claim 1, the polishing time comprising:
a first main polishing time T1m;
a second main polishing time T2m; and
an over-polish polishing time To.

3. The method of claim 2, the first main polishing time T1m comprising applying a higher concentration of Surfactant A during a polishing time during which copper in removed slurry has a wt % concentration of about 0.2.

4. The method of claim 2, the second main polishing time T2m comprising applying a lower concentration of surfactant A for a polishing time during which copper in removed slurry has a wt % concentration of about 0.1.

5. The method of claim 2, the over-polish polishing time comprising applying a Surfactant B to which a chemical component is added as a slurry.

6. The method of claim 5, the chemical component being selected for, relating to copper surfaces:
erosion reduction;
reduction in surface dishing; and
hydrophobic surface wetting of low-k dielectric material.

7. The method of claim 1, Surfactant A comprising a chemical structure of

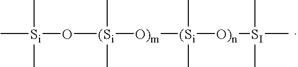

8. The method of claim 1, Surfactant B comprising a chemical structure of

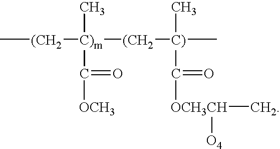

9. A method of reducing copper surface dishing and erosion and low-k dielectric delamination, comprising:
providing a substrate, a patterned layer of copper having been created in a layer of low-k dielectric deposited over the surface of the substrate; and
polishing during three polishing intervals the patterned layer of copper while adjusting a Surface Active Agent (surfactant) of first removed and then re-applied slurry as a function of polishing time, the three polishing intervals comprising:
(i) a first main polishing time T1m, applying a high concentration of Surfactant A;
(ii) a second main polishing time T2m, applying low concentration of Surfactant A; and
(iii) an over-polish polishing time To, applying Surfactant B.

10. The method of claim 7, the high concentration of Surfactant A resulting in removed slurry having a wt % concentration of about 0.2.

11. The method of claim 7, the low concentration of Surfactant A resulting in removed slurry having a wt % concentration of about 0.1.

12. The method of claim 7, the over-polish polishing time To, applying Surfactant B being adjusted for reducing erosion and dishing of the polished surface in addition to increasing low-k dielectric hydrophobic surface wetting, preventing delamination.

13. The method of claim 7, Surfactant A comprising a chemical structure of

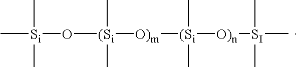

14. The method of claim 7, Surfactant B comprising a chemical structure of

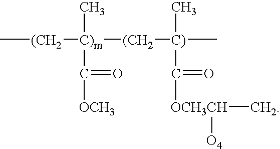

15. A method of reducing copper surface dishing and erosion and low-k dielectric delamination, comprising:
providing a substrate, a patterned layer of copper having been created in a layer of low-k dielectric deposited over the surface of the substrate; and
polishing during three polishing intervals the patterned layer of copper while adjusting a Surface Active Agent (surfactant) of first removed and then re-applied slurry as a function of polishing time, the three polishing intervals comprising:
(i) a first main polishing time T1m, the first main polishing time T1m comprising a polishing time during which copper in removed slurry has a wt % concentration of about 0.2, providing a high concentration of Surfactant A being re-applied to the surface being polished;
(ii) a second main polishing time T2m, the first main polishing time T1m comprising a polishing time during which copper in removed slurry has a wt % concentration of about 0.1, providing a low concentration of Surfactant A being re-applied to the surface being polished; and
(iii) an over-polish polishing time To, applying a Surfactant B to the surface being polished.

16. The method of claim 15, the over-polish polishing time To comprising a polishing time during which a chemical component is added to the slurry.

17. The method of claim 15, Surfactant A comprising a chemical structure of

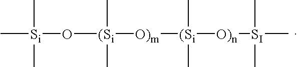

18. The method of claim 15, Surfactant B comprising a chemical structure of

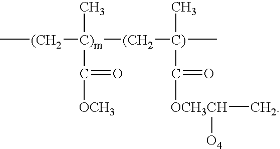

19. A method of reducing copper surface dishing and erosion and low-k dielectric delamination, comprising:
providing a substrate, a patterned layer of copper having been created in a layer of low-k dielectric deposited over the surface of the substrate; and
polishing during three polishing intervals the patterned layer of copper while removing and then re-applying slurry as a function of polishing time.

20. The method of claim 19, the removing and then re-applying slurry as a function of polishing time comprising adjusting a Surface Active Agent (surfactant) of the removed and then re-applied slurry.

21. The method of claim 19, the polishing time comprising:
a first main polishing time T1m comprising applying a low concentration of Surfactant A as a slurry;
a second main polishing time T2m comprising applying a low concentration of surfactant A as a slurry; and
an over-polish polishing time To comprising applying a Surfactant B as a slurry.

22. The method of claim 21, the first main polishing time T1m comprising a polishing time during which copper in removed slurry has a wt % concentration of about 0.2.

23. The method of claim 21, the second main polishing time T2m comprising a polishing time during which copper in removed slurry has a wt % concentration of about 0.1.

24. The method of claim 21, the over-polish polishing time To comprising a polishing time during which a chemical component is added to the slurry.

25. The method of claim 24, the chemical component being selected for, relating to copper surfaces:
erosion reduction;
reduction in surface dishing; and
hydrophobic surface wetting of low-k dielectric material.

26. The method of claim 21, Surfactant A comprising a chemical structure of

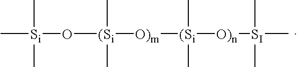

27. The method of claim 21, Surfactant B comprising a chemical structure of

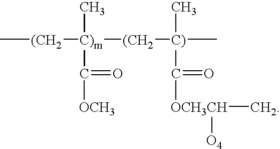

28. A method of reducing copper surface dishing and erosion and low-k dielectric delamination, comprising:
providing a substrate, a patterned layer of copper having been created in a layer of low-k dielectric deposited over the surface of the substrate; and
polishing during three polishing intervals the patterned layer of copper while removing and then re-applying slurry as a function of polishing time, the three polishing intervals comprising:
(i) a first main polishing time T1m, the first main polishing time T1m comprising a polishing time during which copper in removed and re-applied slurry has a wt % concentration of about 0.2, forming a high concentration of Surfactant A;
(ii) a second main polishing time T2m, the first main polishing time T1m comprising a polishing time during which copper in removed and re-applied slurry has a wt % concentration of about 0.1, forming a low concentration of Surfactant A; and
(iii) an over-polish polishing time To, applying a Surfactant B as a slurry.

29. The method of claim 28, the over-polish polishing time To comprising a polishing time during which a chemical component is added to the slurry.

30. The method of claim 28, Surfactant A comprising a chemical structure of

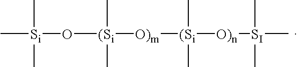

31. The method of claim 28, Surfactant B comprising a chemical structure of

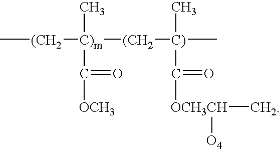

32. A Surfactant for polishing a semiconductor surface having a chemical structure of:

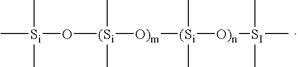

33. A Surfactant for polishing a semiconductor surface having a chemical structure of: [chemical structure]
